(19) United States
(12) Patent Application Publication
(10) Pub. No.: US 2020/0334439 A1
(43) Pub. Date: Oct. 22, 2020

(54) ARRAY SUBSTRATE, DISPLAY PANEL, DISPLAY DEVICE, METHOD OF FINGERPRINT IDENTIFICATION AND TOUCH CONTROL METHOD

(71) Applicant: BOE TECHNOLOGY GROUP CO., LTD., Beijing (CN)

(72) Inventors: Yanliu SUN, Beijing (CN); Dawei WANG, Beijing (CN); Shiming SHI, Beijing (CN)

(21) Appl. No.: 16/621,609

(22) PCT Filed: May 31, 2019
(86) PCT No.: PCT/CN2019/089420

§ 371 Date: Dec. 11, 2019

(30) Foreign Application Priority Data
Aug. 17, 2018 (CN) 201810939143.7

(51) Int. Cl. G06K 9/00; G06F 3/042; H01L 27/32; H01L 51/00

(52) U.S. Cl. CPC G06K 9/0004; G06F 3/0421; H01L 27/14678; H01L 27/3272; H01L 51/0097; H01L 27/3234

(57) ABSTRACT

An array substrate, a display panel, a display device, a method of fingerprint identification and a touch control method are provided. The array substrate includes: a base substrate, a light-emitting component on the base substrate, a light sensor located on a side of the base substrate that is remote from the light-emitting component and a light-shielding layer between the light-emitting component and the base substrate. The light-shielding layer has a plurality of holes arranged in an array. Projections of the holes on the base substrate do not overlap with a projection of the light-emitting component on the base substrate and fall within a projection of the light sensor on the base substrate.

### CROSS-REFERENCE TO RELATED APPLICATIONS

This application is a U.S. national phase application of a PCT Application No. PCT/CN2019/089420 filed on May 31, 2019, which claims a priority to Chinese Patent Application No. 201810939143.7 filed on Aug. 17, 2018, the disclosures of which are incorporated in their entirety by reference herein.

### TECHNICAL FIELD

The present disclosure relates to the field of display technology, in particular to an array substrate, a display panel, a display device, a method of fingerprint identification and a touch control method.

### BACKGROUND

Fingerprints are invariant features that are innate and distinguishable from each other. The fingerprints include a series of ridges and valleys on a skin surface. These ridges and valleys dictate the uniqueness of a fingerprint pattern. Therefore, fingerprint identification is applied to identity authentication, which may enhance information security of a device.

As a newly emerged computer input device, touch screen replaces mechanical button-based panel with a tactile feedback system, thereby providing a simple, convenient and natural way of human-machine interaction.

### SUMMARY

An array substrate, a display panel, a display device, a method of fingerprint identification and a touch control method are provided by embodiments of the present disclosure.

It is an object of some embodiments of the present disclosure to provide an array substrate. The array substrate includes: a base substrate; a light-emitting component on the base substrate; a light sensor located on a side of the base substrate that is remote from the light-emitting component; a light-shielding layer between the light-emitting component and the base substrate, where the light-shielding layer has a plurality of holes arranged in an array, projections of the holes on the base substrate do not overlap with a projection of the light-emitting component on the base substrate and fall within a projection of the light sensor on the base substrate, the array includes at least two sub-arrays, each of the sub-arrays includes at least two holes, a minimum distance from a hole in a sub-array of the sub-arrays to a hole in an adjacent sub-array of the sub-arrays is greater than a distance between two adjacent holes in the same sub-array.

In an embodiment, the light-emitting component includes an organic light emitting diode (OLED) device.

In an embodiment, the sub-array includes the holes arranged in form of a 10×10 array.

In an embodiment, a diameter of the holes ranges from 5 microns to 20 microns.

In an embodiment, the light-shielding layer includes a metal.

In an embodiment, the light sensor includes at least one of a charge coupled device (CCD) light sensor and a complementary metal oxide semiconductor (CMOS) light sensor.

In an embodiment, the base substrate includes a flexible base.

In an embodiment, the array substrate further includes a positioning device. The positioning device is configured to determine a position of a touch object based on an incident position at which a light reflected by the touch object and passing through the holes is incident to the light sensor when the touch object touches the array substrate.

In an embodiment, the array substrate further includes a fingerprint identification device. The fingerprint identification device is configured to acquire a fingerprint image from the light sensor when the touch object is a finger.

It is another object of some embodiments of the present disclosure to provide a display panel. The display panel includes the array substrate as described above and a covering plate arranged opposite to the array substrate. The light-emitting component of the array substrate faces to the covering plate.

It is yet another object of some embodiments of the present disclosure to provide a display device. The display device includes the display panel as described above.

It is still another object of some embodiments of the present disclosure to provide a method of fingerprint identification using the array substrate as described above. The method includes: acquiring a fingerprint image from the light sensor when a finger touches the array substrate.

It is still another object of some embodiments of the present disclosure to provide a touch control method using the array substrate as described above. The touch control method includes: determining a touch position of a touch object based on an incident position at which a light reflected by the touch object and passing through the holes is incident to the light sensor when the touch object touches the array substrate.

In an embodiment, the light sensor has sensing regions in one-to-one correspondence with the sub-arrays. The method includes: using a position of the sensing region at which a light reflected from the touch object is received as the touch position of the touch object.

### BRIEF DESCRIPTION OF THE DRAWINGS

In order to more clearly illustrate the technical solutions of the embodiments of the present disclosure, the drawings of the embodiments will be briefly described below. It should be understood that the drawings described below are merely illustrative of some embodiments of the present disclosure and are not intended to limit the present disclosure.

FIG. 1A is a schematic cross-sectional view of an array substrate according to some embodiments of the present disclosure;

FIG. 1B is a schematic top view of an array substrate according to some embodiments of the present disclosure;

FIG. 2 is a schematic view of an array substrate according to some embodiments of the present disclosure;

FIG. 3 is a schematic view of a display panel according to some embodiments of the present disclosure;

FIG. 4 is a schematic view of a display device according to some embodiments of the present disclosure;

FIG. 5 illustrates fingerprint images, where a left image (a) is the fingerprint image in an example, and a right image (b) is the fingerprint image derived from the array substrate according to some embodiments of the present disclosure;

FIG. 6 is a schematic view of a touch position identification according to some embodiments of the present disclosure.

### DETAILED DESCRIPTION

In order to make the objects, technical solutions and advantages of the embodiments of the present disclosure more clear, the technical solutions of the embodiments of the present disclosure will be clearly and completely described below in conjunction with the drawings of the embodiments of the present disclosure. It is apparent that the described embodiments are a part of the embodiments of the present disclosure, and not all of them. All other embodiments obtained by those skilled in the art based on the described embodiments of the present disclosure fall within the scope of the disclosure.

When introducing elements of the present disclosure and the embodiments thereof, unless the context clearly indicates, otherwise, the singular forms of words used herein and in the appended claims include the plural, and vice versa. Thus, when a singular term is referred to, generally plural form is included. The terms “comprising”, “including”, “containing” and “having” are intended to be inclusive and mean that there may be additional elements apart from the listed elements.

For the purposes of the description of surfaces below, as oriented in the drawings, the terms “upper”, “lower”, “left”, “right”, “vertical”, “horizontal”, “top”, “bottom” and their derivatives should be related to the disclosure. The term “overlay”, “on top of”, “positioned on” or “positioned on top of” means that a first element, such as a first structure, exists on a second element, such as a second structure. There may be intermediate elements such as an interface structure between the first element and the second element. The term “contacting” means connecting a first element such as a first structure and a second element such as a second structure. There may or may not be other elements at the interface of the two elements.

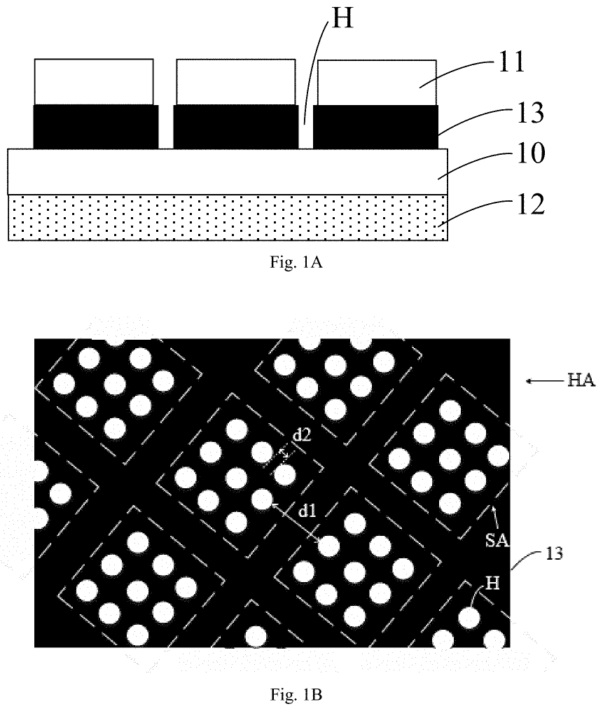

FIG. 1A is a schematic cross-sectional view of an array substrate according to some embodiments of the present disclosure. As shown in FIG. 1A, The array substrate according to some embodiments of the present disclosure includes: a base substrate 10, a light-emitting component 11 on the base substrate 10, a light sensor 12 located on a side of the base substrate 10 that is remote from the light-emitting component 11, a light-shielding layer 13 between the light-emitting component 11 and the base substrate 10. The light-shielding layer 13 has a plurality of holes H arranged in an array, projections of the holes 13 on the base substrate 10 do not overlap with a projection of the light-emitting component 11 on the base substrate 10 and fall within a projection of the light sensor 12 on the base substrate 10.

FIG. 1B is a schematic top view of an array substrate according to some embodiments of the present disclosure. In FIG. 1B, the light-emitting component 11 is not shown. As shown in FIG. 1B, the array HA made up of a plurality of holes H includes at least two sub-arrays SA. Each of the sub-arrays SA includes at least two holes H. A minimum distance d1 from a hole H in a sub-array SA to a hole H in an adjacent sub-array SA is greater than a distance d2 between two adjacent holes H in the same sub-array.

In some embodiments of the present disclosure, a fingerprint imaging is achieved through holes, thereby enabling a fingerprint identification. By imaging with the array of holes, a fingerprint may be segmented, thereby avoiding the problem suffered by the pin-hole imaging that an image edge blurs and improving the imaging quality. By means of a receiving position of the fingerprint image on the light sensor, a position identification of a fingerprint image may be achieved, and the receiving position is used as the touch position. Therefore, in the embodiments of the present disclosure, the fingerprint imaging function and the touch function may be integrated into a back plate, and the fingerprint identification and the touch control are enabled in a display region, thereby facilitating the implementation of a full screen and a narrow bezel. Furthermore, embodiments of the present disclosure also reduce manufacturing costs and size.

The minimum distance from a hole in a sub-array to a hole in an adjacent sub-array is more than twice the distance between two adjacent holes in the same sub-array. According to such a setting, an interference between adjacent sub-arrays may be avoided, thereby achieving a better fingerprint imaging effect.

The sub-array SA in form of a 3×3 array as shown in FIG. 1B is exemplary, and the number of rows and the number of columns of the sub-array may be set as needed. For example, the sub-array may be set in form of a 10x10 array to obtain a better display effect.

A diameter of the hole needs to meet the requirement on the diameter of a pinhole according to the principle of the pinhole imaging. For example, the diameter of the hole ranges from about 5 microns (μm) to 20 microns. In the case that the diameter of the hole is larger than 20 μm, a resolution of the formed fingerprint image is impacted. In the case that the diameter of the hole is less than 5 μm, an illumination level on the light sensor is low, thereby impacting the imaging effect.

The light-emitting device may be an OLED component. Thus, for an OLED display device, it is not necessary to separately provide a light source for fingerprint identification, since the OLED device used for display may act as the light source. The light-shielding layer may include a metal and any other suitable light shielding material. The light sensor may include at least one of a CCD light sensor and a CMOS light sensor. The base substrate may include a flexible substrate. For example, the base substrate may be a polyimide (PI) substrate.

It should be noted that one or more light sensors may be provided in the array substrate. For example, the fingerprint identification may be performed based on images formed by the holes in different regions of the same light sensor. For example, the fingerprint identification may be performed based on images formed by the holes in respective sensors.

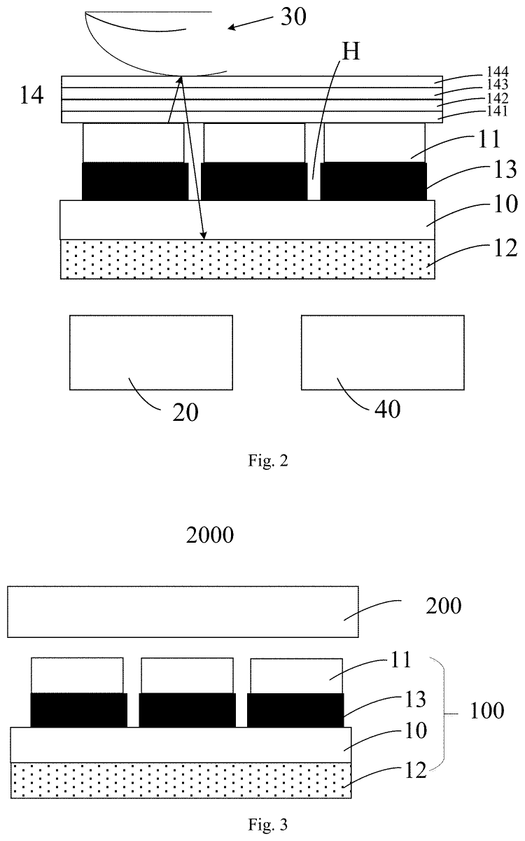

FIG. 2 is a schematic view of an array substrate according to some embodiments of the present disclosure. As shown in FIG. 2, the array substrate according to the embodiments of the present disclosure may further include a positioning device 20. The positioning device 20 is configured to determine a position of a touch object 30 based on an incident position at which a light reflected by the touch object 30 and passing through the holes H is incident to the light sensor 21 when the touch object 30 touches the array substrate.

As shown in FIG. 2, the array substrate according to some embodiments of the present disclosure may further include a fingerprint identification device 40. The fingerprint identification device 40 is configured to acquire a fingerprint image from the light sensor 12 when the touch object 30 is a finger.

The positioning device 20 and the fingerprint identification device 40 may be implemented as a combination of a processor and a storage. The processor executes a program stored in the storage to implement the function of a corresponding unit or module. The unit or module described herein may also be implemented in hardware completely, which including an application specific integrated circuit (ASIC), a field programmable gate array (FPGA), and the like.

The array substrate may also include a covering layer 14 on the light-emitting component 11. The covering layer 14 may include a first adhesive layer 141, a polarizer 142, a second adhesive layer 143 and a spacer layer (such as glass) 144 arranged from bottom to top. Here, “bottom” refers to a direction toward the base substrate 10, and “top” refers to a direction away from the base substrate 10.

FIG. 3 is a schematic view of a display panel according to some embodiments of the present disclosure. As shown in FIG. 3, the display panel 2000 according to some embodiments of the present disclosure may include the array substrate 100 as described above and a covering plate 200 arranged opposite to the array substrate 100. For example, the array substrate 100 may be the array substrate as shown in any one of FIG. 1A, FIG. 1B and FIG. 2.

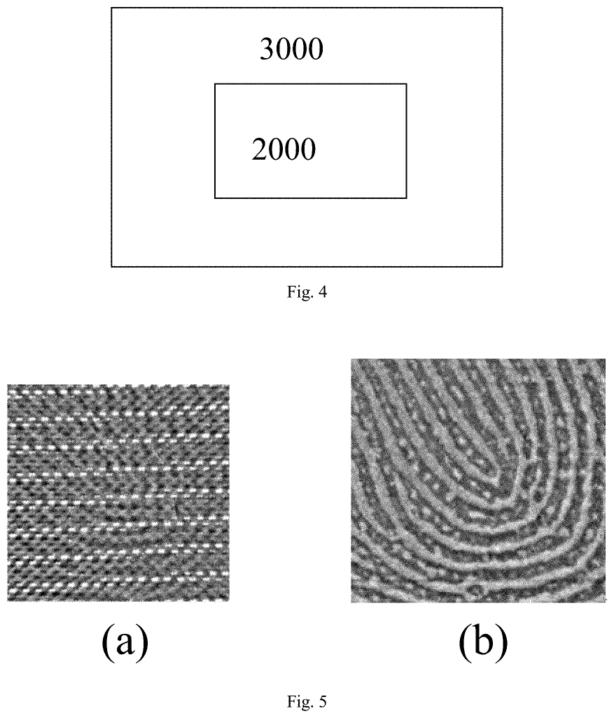

FIG. 4 is a schematic view of a display device according to some embodiments of the present disclosure. As shown in FIG. 4, the display device 3000 according to some embodiments of the present disclosure may include the display panel 2000 as described above. The display panel may be the display panel 2000 shown in FIG. 3.

The display device provided by some embodiments of the present disclosure may be any product or component having a display function, such as a display panel, a mobile phone, a tablet computer, a television, a notebook computer, a digital photo frame, or a navigator.

FIG. 5 illustrates fingerprint images, where a left image (a) in FIG. 5 is the fingerprint image in an example, and a right image (b) in FIG. 5 is the fingerprint image derived from the array substrate according to some embodiments of the present disclosure (a case in which the holes of the sub-array are arranged in form of 10x10 array is taken as an example). It can be seen in FIG. 5 that, the fingerprint image according to some embodiments of the present disclosure is clearer and has a better imaging quality.

A method of fingerprint identification using the array substrate as described above is provided by some embodiments of the present disclosure. The method includes: acquiring the fingerprint image from the light sensor when a finger touches the array substrate.

A touch control method using the array substrate is provided by some embodiments of the present disclosure. The method includes: determining a touch position of a touch object based on an incident position at which a light reflected by the touch object and passing through the holes is incident to the light sensor when the touch object touches the array substrate.

The light sensor may have sensing regions in one-to-one correspondence with the sub-arrays. The method according to some embodiments of the present disclosure includes: using a position of the sensing region at which a light reflected from the touch object is received as the touch position of the touch object.

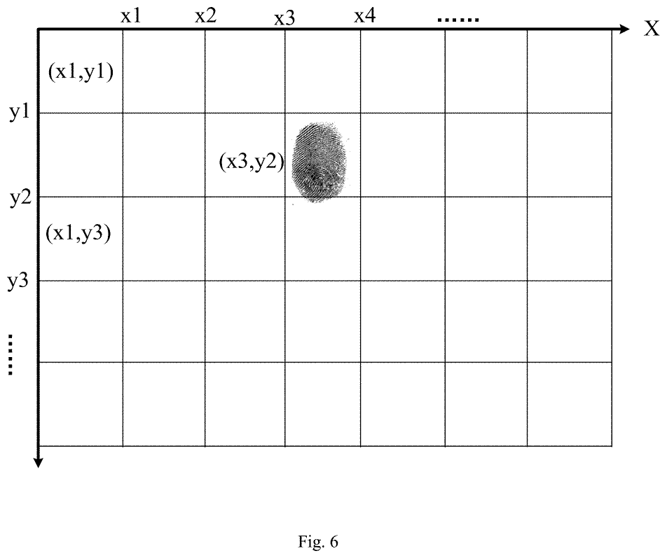

FIG. 6 is a schematic view of a touch position identification according to some embodiments of the present disclosure, in which a finger is taken as an example of the touch object. As shown in FIG. 6, the light sensor is divided into sensing regions having different coordinates in a first direction (e.g., the X direction) and a second direction (e.g., the Y direction) perpendicular to the first direction, for example, (x1, y1), (x1, y3), (x3, y2), and the like. The touch position of the touch object is determined according to the position of the sensing region at which the light reflected from the touch object is received. Thereby, touch instructions are identified and executed according to the touch positions. For example, as shown in FIG. 6, the sensing region corresponding to the fingerprint image (i.e., the light reflected from the finger) is (x4, y2). At this time, the touch position is identified to be (x4, y2). Then, the touch instruction may be identified and executed according to the touch position of (x4, y2). It may be understood that if the fingerprint image occupies two or more sensing regions, a region in which the fingerprint image occupies the most area may be identified as the corresponding sensing region.

Some particular embodiments have been described, however these embodiments are presented by way of example only and are not intended to limit the scope of the present disclosure. In fact, some novel embodiments described herein may be implemented in a variety of other forms. In addition, various forms of omissions, substitutions and changes may be made in the embodiments described herein without departing from the spirit of the present disclosure. The following claims and their equivalents are intended to cover such forms or modifications that fall within the scope and spirit of the present disclosure.

1. An array substrate, comprising:
a base substrate;
a light-emitting component on the base substrate;
a light sensor located on a side of the base substrate that is remote from the light-emitting component;
a light-shielding layer between the light-emitting component and the base substrate, wherein the light-shielding layer has a plurality of holes arranged in an array, projections of the holes on the base substrate do not overlap with a projection of the light-emitting component on the base substrate and fall within a projection of the light sensor on the base substrate, the array comprises at least two sub-arrays, each of the sub-arrays comprises at least two holes, a minimum distance from a hole in a sub-array of the sub-arrays to a hole in an adjacent sub-array of the sub-arrays is greater than a distance between two adjacent holes in the sub-array.

2. The array substrate according to claim 1, wherein the minimum distance from a hole in a sub-array of the sub-arrays to a hole in an adjacent sub-array of the sub-arrays is more than twice the distance between two adjacent holes in the sub-array.

3. The array substrate according to claim 1, wherein the light-emitting component comprises an OLED component.

4. The array substrate according to claim 1, wherein the sub-array comprises the holes arranged in form of a 10×10 array.

5. The array substrate according to claim 4, wherein a diameter of the holes ranges from 5 microns to 20 microns.

6. The array substrate according to claim 1, wherein the light-shielding layer comprises a metal.

7. The array substrate according to claim 1, wherein the light sensor comprises at least one of a CCD light sensor and a CMOS light sensor.

8. The array substrate according to claim 1, wherein the base substrate comprises a flexible base.

9. The array substrate according to claim 1, further comprising a positioning device, wherein the positioning device is configured to determine a position of a touch object based on an incident position at which a light reflected by the touch object and passing through the holes is incident to the light sensor when the touch object touches the array substrate.

10. The array substrate according to claim 9, further comprising a fingerprint identification device, wherein the fingerprint identification device is configured to acquire a fingerprint image from the light sensor when the touch object is a finger.

11. A display panel, comprising the array substrate according to claim 1 and a covering plate arranged opposite to the array substrate, wherein the light-emitting component of the array substrate faces to the covering plate.

12. A display device, comprising the display panel according to claim 11.

13. A method of fingerprint identification using the array substrate according to claim 1, comprising: acquiring a fingerprint image from the light sensor when a finger touches the array substrate.

14. A touch control method using the array substrate according to claim 1, comprising: determining a touch position of a touch object based on an incident position at which a light reflected by the touch object and passing through the holes is incident to the light sensor when the touch object touches the array substrate.

15. The touch control method according to claim 14, wherein the light sensor has sensing regions in one-to-one correspondence with the sub-arrays, and the method comprises using a position of the sensing region at which a light reflected from the touch object is received as the touch position of the touch object.
